(19) United States
(12) Patent Application Publication
(10) Pub. No.: US 2025/0169062 A1
(43) Pub. Date: May 22, 2025

(54) SEMICONDUCTOR DEVICE

(71) Applicant: Samsung Electronics Co., Ltd., Suwon-si (KR)

(72) Inventors: Jungmin PARK, Suwon-si (KR); Jisung KIM, Suwon-si (KR); Beomjong KIM, Suwon-si (KR); Hyungsuk JUNG, Suwon-si (KR)

(73) Assignee: Samsung Electronics Co., Ltd., Suwon-si (KR)

(21) Appl. No.: 18/936,133

(22) Filed: Nov. 4, 2024

(30) Foreign Application Priority Data
Nov. 21, 2023 (KR) 10-2023-0162718

(51) Int. Cl. H10B 12/00; H01L 29/51

(52) U.S. Cl. CPC H10B 12/315; H10D 64/689; H10D 64/691

(57) ABSTRACT

Provided is a semiconductor device including a lower electrode, an upper electrode on the lower electrode, and a dielectric layer structure between the lower electrode and the upper electrode. The dielectric layer structure includes a first dielectric layer in contact with the lower electrode, a second dielectric layer in contact with the first dielectric layer, and a third dielectric layer in contact with the upper electrode. The first dielectric layer, the second dielectric layer, and the third dielectric layer include an anti-ferroelectric material. The anti-ferroelectric material of the first, second, and third dielectric layers are of the same material type, and a silicon dopant is included in a region adjacent to an interface between the first dielectric layer and the lower electrode, and a region adjacent to an interface between the third dielectric layer and the upper electrode.

### CROSS-REFERENCE TO RELATED APPLICATION

This application is based on and claims priority under 35 U.S.C. § 119 to Korean Patent Application No. 10-2023-0162718, filed on Nov. 21, 2023, in the Korean Intellectual Property Office, the disclosure of which is incorporated by reference herein in its entirety.

### BACKGROUND

The inventive concepts relate to a semiconductor device. More particularly, the inventive concepts relate to a semiconductor device including an anti-ferroelectric material.

According to the high integration trends of semiconductor devices, individual circuit patterns are further refined to implement more semiconductor devices in a same area. That is, as the degree of integration of semiconductor devices increases, the design rules for components of semiconductor devices are decreasing. Accordingly, there is a demand for a semiconductor devices capable of maintaining electrical characteristics by overcoming the limitations of design rules.

### SUMMARY

The inventive concepts provide semiconductor devices with improved operation reliability.

According to an aspect of the inventive concepts, there is provided a semiconductor device including a lower electrode, an upper electrode on the lower electrode, and a dielectric layer structure between the lower electrode and the upper electrode. The dielectric layer structure includes a first dielectric layer in contact with the lower electrode, a second dielectric layer in contact with the first dielectric layer, and a third dielectric layer in contact with the upper electrode. The first dielectric layer, the second dielectric layer, and the third dielectric layer include an anti-ferroelectric material. The anti-ferroelectric material of the first, second, and third dielectric layers are of the same material type, and a silicon dopant is included in a region adjacent to an interface between the first dielectric layer and the lower electrode, and a region adjacent to an interface between the third dielectric layer and the upper electrode.

According to another aspect of the inventive concepts, there is provided a semiconductor device including a lower electrode, an upper electrode on the lower electrode, and a dielectric layer structure between the lower electrode and the upper electrode. The dielectric layer structure includes a first dielectric layer in contact with the lower electrode, a second dielectric layer in contact with the first dielectric layer, and a third dielectric layer in contact with the upper electrode. The second dielectric layer includes a plurality of ferroelectric material layers and a plurality of anti-ferroelectric material layers alternately stacked, and a silicon dopant is included in at least one of a region adjacent to an interface between the first dielectric layer and the lower electrode, and a region adjacent to an interface between the third dielectric layer and the upper electrode.

According to another aspect of the inventive concepts, there is provided a semiconductor device including a substrate having a plurality of active regions defined by device isolation layers, a lower structure on the substrate and connected to the plurality of active regions, and a capacitor structure on the lower structure and connected to the lower structure. The capacitor structure includes a lower electrode, an upper electrode on the lower electrode, and a dielectric layer structure between the lower electrode and the upper electrode. The dielectric layer structure includes a first dielectric layer in contact with the lower electrode, a second dielectric layer in contact with the first dielectric layer, and a third dielectric layer in contact with the upper electrode. Each of the first dielectric layer, the second dielectric layer, and the third dielectric layer includes at least one of HfO2 and ZrO2, and a silicon dopant is included inside of the first dielectric layer and inside of the third dielectric layer.

### BRIEF DESCRIPTION OF THE DRAWINGS

Various example embodiments of the inventive concepts will be more clearly understood from the following detailed description taken in conjunction with the accompanying drawings in which:

FIG. 1 is a layout diagram schematically illustrating components of a semiconductor device according to various example embodiments;

FIG. 2 is a cross-sectional view taken along a line A-A′ of FIG. 1;

FIG. 3 is an enlarged cross-sectional view of a region EX of FIG. 2;

FIGS. 4, 5, 6, 7, and 8 are enlarged cross-sectional views illustrating a region corresponding to the region EX illustrated in FIG. 2;

FIG. 9 is a layout diagram schematically illustrating components of a semiconductor device according to various example embodiments;

FIG. 10 is a cross-sectional view taken along a line B-B′ of FIG. 9;

FIG. 11 is an enlarged cross-sectional view of a region EX′ of FIG. 10;

FIG. 12 is an enlarged cross-sectional view of a region EX″ of FIG. 11; and

FIGS. 13A, 13B, 13C, 13D, 13E, 13F, 13G, and 13H are cross-sectional views illustrating methods of manufacturing a semiconductor device, according to various example embodiments.

### DETAILED DESCRIPTION

Hereinafter, various example embodiments of the inventive concepts will be described in detail with reference to the accompanying drawings. The same reference numerals are used for the same components in the drawings, and redundant descriptions thereof are omitted.

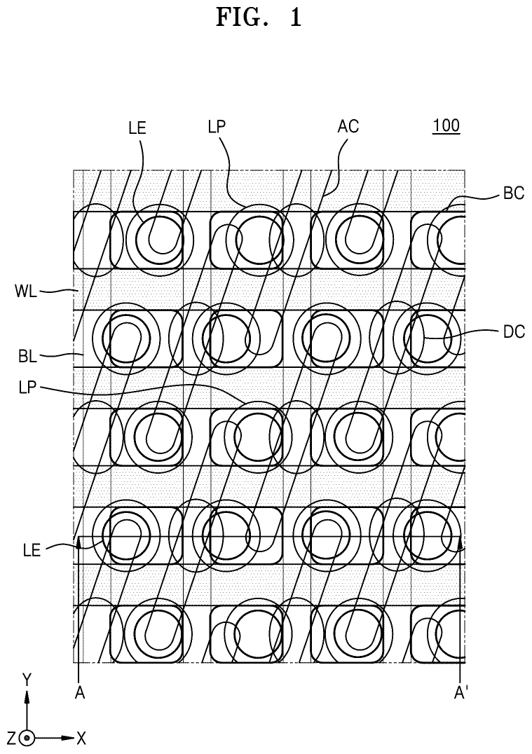

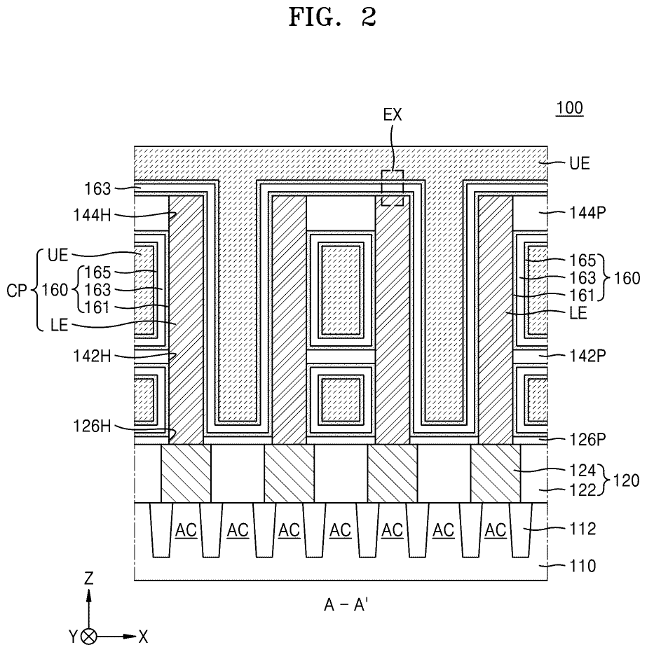

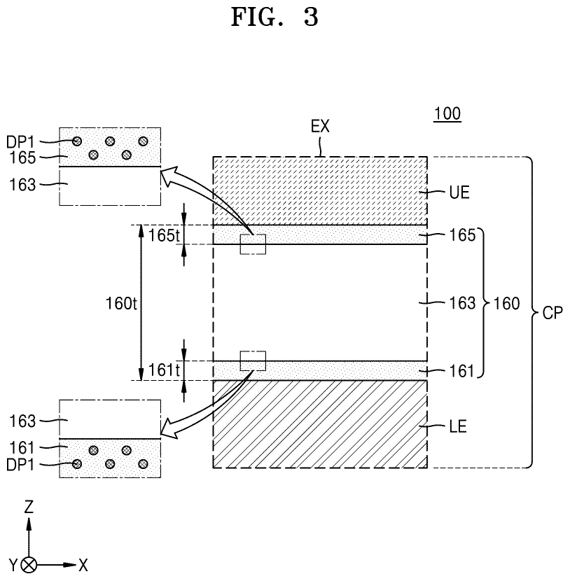

FIG. 1 is a layout diagram schematically illustrating components of a semiconductor device 100 according to various example embodiments. FIG. 2 is a cross-sectional view taken along a line A-A′ of FIG. 1. FIG. 3 is an enlarged cross-sectional view of a region EX of FIG. 2.

Referring to FIG. 1, a semiconductor device 100 may include a plurality of active regions AC arranged to have a long axis in a diagonal direction with respect to a first horizontal direction (X direction) and a second horizontal direction (Y direction). A plurality of word lines WL may extend in parallel to each other in the first direction (X direction) across the plurality of active regions AC. A plurality of bit lines BL may extend in parallel with each other in the second horizontal direction (Y direction) on the plurality of word lines WL. Each of the plurality of bit lines BL may be connected to an active region AC through a direct contact DC.

A plurality of buried contacts BC may be arranged between two bit lines BL adjacent to each other among the plurality of bit lines BL. A plurality of landing pads LP may be arranged on the plurality of buried contacts BC. At least a portion of each of a plurality of landing pads LP may overlap the buried contacts BC in a vertical direction (Z direction). Each of a plurality of lower electrodes LE may be arranged on each of the plurality of landing pads LP to be spaced apart from each other. The plurality of lower electrodes LE may be connected to the plurality of active regions AC through the plurality of buried contacts BC and the plurality of landing pads LP.

Referring to FIGS. 2 and 3, the semiconductor device 100 may include a substrate 110 including the plurality of active regions AC, a lower structure 120 arranged on the substrate 110, and a plurality of capacitor structures CP arranged on the lower structure 120.

The substrate 110 may include a semiconductor element such as Si and Ge, or a compound semiconductor such as SiC, GaAs, InAs, and InP. However, example embodiments are not limited thereto. The substrate 110 may include a semiconductor substrate, or structures including at least one insulating layer formed on the semiconductor substrate or at least one conductive region. The conductive region may include, for example, a well doped with impurities or a structure doped with impurities.

Device isolation layers 112 that define the plurality of active regions AC may be formed on the substrate 110. The device isolation layers 112 may include an oxide layer, a nitride layer, or a combination thereof. In various example embodiments, the device isolation layers 112 may have various structures such as a shallow trench isolation (STI) structure.

The lower structure 120 may include a plurality of conductive regions 124 and a plurality of insulating structures 122. The plurality of conductive regions 124 may penetrate the lower structure 120 in the vertical direction (Z direction) to be connected to the plurality of active regions AC. The plurality of conductive regions 124 may be insulated from each other by the plurality of insulating structures 122. Each of the plurality of insulating structures 122 may include an insulating layer including a silicon oxide layer, a silicon nitride layer, or a combination thereof. In some other example embodiments, the plurality of insulating structures 122 may each include various conductive regions, for example, a wiring layer, a contact plug, a transistor, and the like, and an insulating layer insulating the various conductive regions from each other.

The plurality of conductive regions 124 may include polysilicon, metal, conductive metal nitride, metal silicide, or a combination thereof. However, example embodiments are not limited thereto. The plurality of conductive regions 124 may include the plurality of bit lines BL described with reference to FIG. 1. Each of the plurality of conductive regions 124 may include the buried contact BC and the landing pad LP described with reference to FIG. 1.

An insulating pattern 126P may be arranged on the lower structure 120. The insulating pattern 126P may have a plurality of openings 126H overlapping the plurality of conductive regions 124 in a vertical direction (Z direction). The insulating pattern 126P may include a silicon nitride (SiN) layer, a silicon carbon nitride (SiCN) layer, a silicon boron nitride (SiBN) layer, or a combination thereof. However, example embodiments are not limited thereto. As used herein, the terms “SiN”, “SiCN”, and “SiBN” refer to materials including elements included in each term, and are not chemical formulas representing a stoichiometric relationship.

A plurality of capacitor structures CP may be arranged on the plurality of conductive regions 124. The plurality of capacitor structures CP may include a plurality of lower electrodes LE, a plurality of dielectric layer structures 160, and upper electrodes UE.

The plurality of lower electrode LE may be arranged on the plurality of conductive regions 124. Each of the plurality of lower electrodes LE may have a pillar shape that penetrates the insulating pattern 126P through each of the plurality of openings 126H and extends long in a direction away from the substrate 110 in the vertical direction (Z direction). Each of the plurality of lower electrodes LE may have a bottom surface in contact with a top surface of one conductive region 124 to be connected to the one conductive region 124 selected from among the plurality of conductive regions 124.

Although FIG. 2 illustrates that each of the plurality of lower electrodes LE has a pillar shape, the various example embodiments of the inventive concepts are not limited thereto. For example, each of the plurality of lower electrodes LE may have a cross-sectional structure of a cup shape, or a cylindrical shape in which the bottom portion is closed.

The plurality of lower electrodes LE may be supported by the lower supporter 142P and the upper supporter 144P. The plurality of lower electrodes LE and the upper electrode UE may face each other with the dielectric layer structures 160 therebetween, respectively.

The upper supporter 144P may surround a top end portion of each of the plurality of lower electrodes LE, and may extend in parallel to the substrate 110. A plurality of holes 144H penetrating by the plurality of lower electrodes LE may be formed in the upper supporter 144P. The inner sidewall of each of the plurality of holes 144H formed in the upper supporter 144P may be in contact with the sidewall of the lower electrode LE. A top surface of each of the plurality of lower electrodes LE and a top surface of the upper supporter 144P may be positioned to be coplanar.

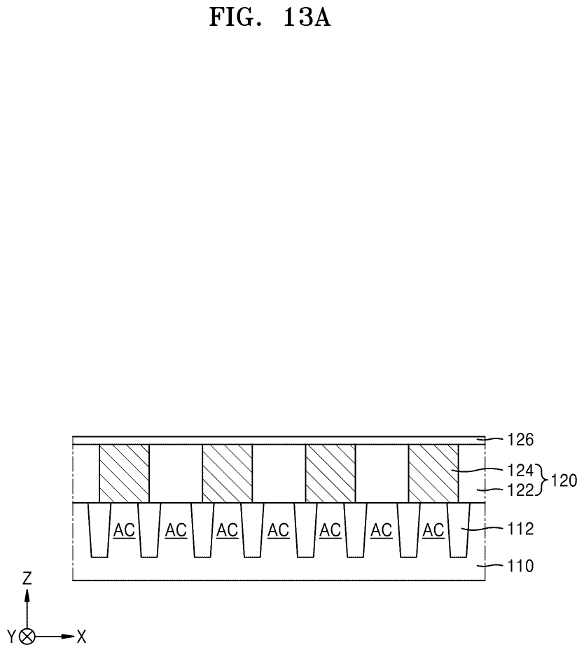

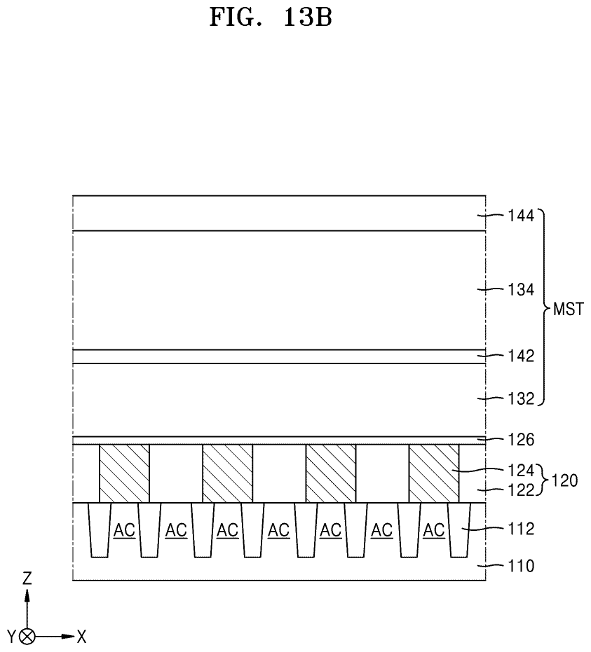

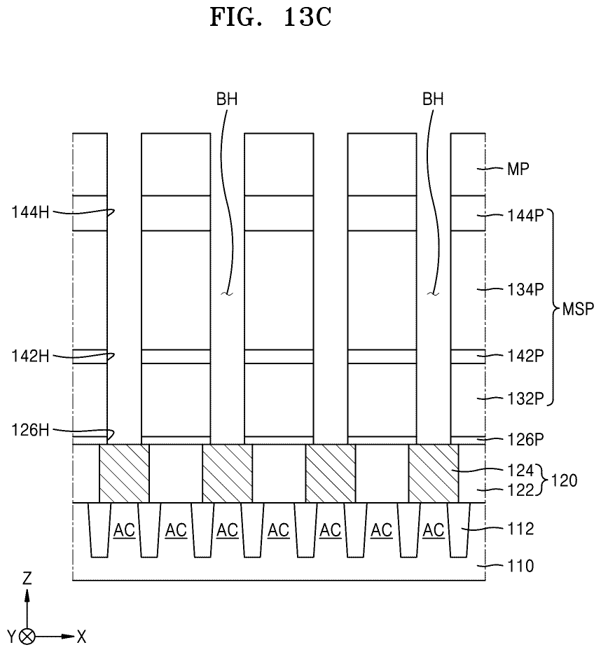

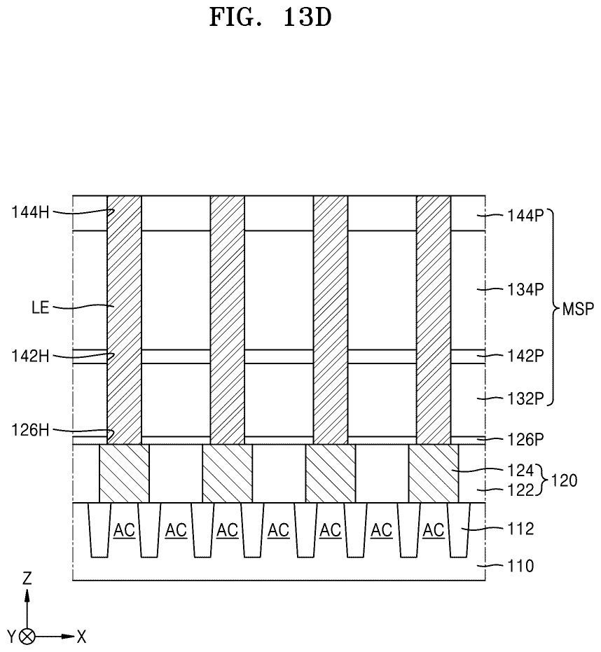

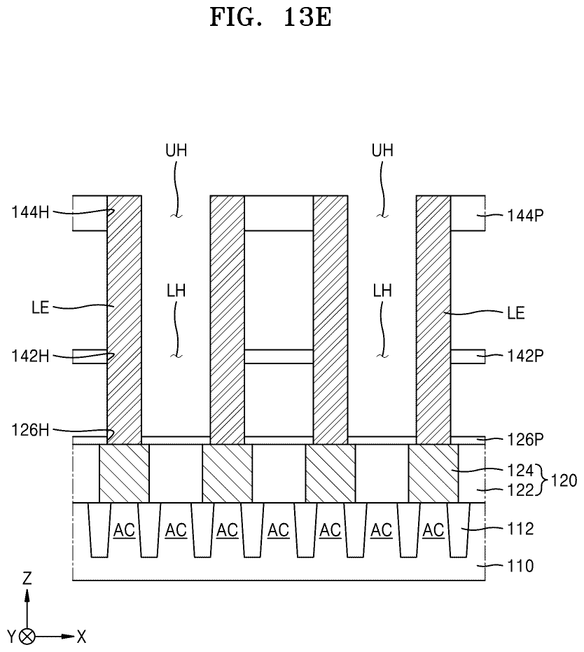

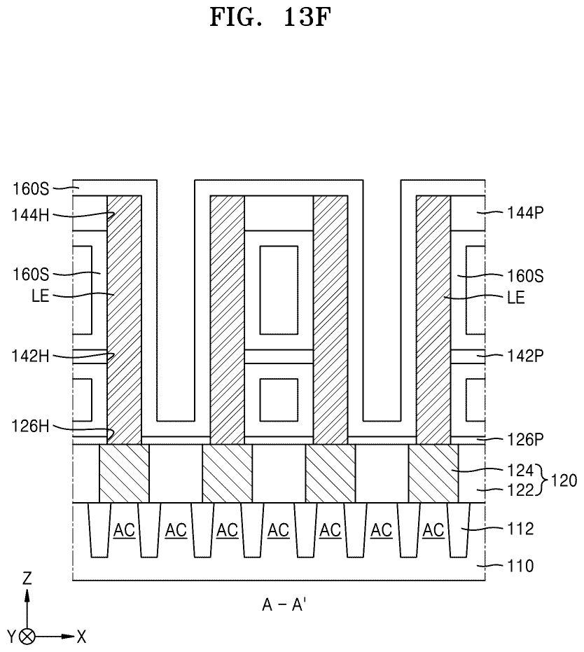

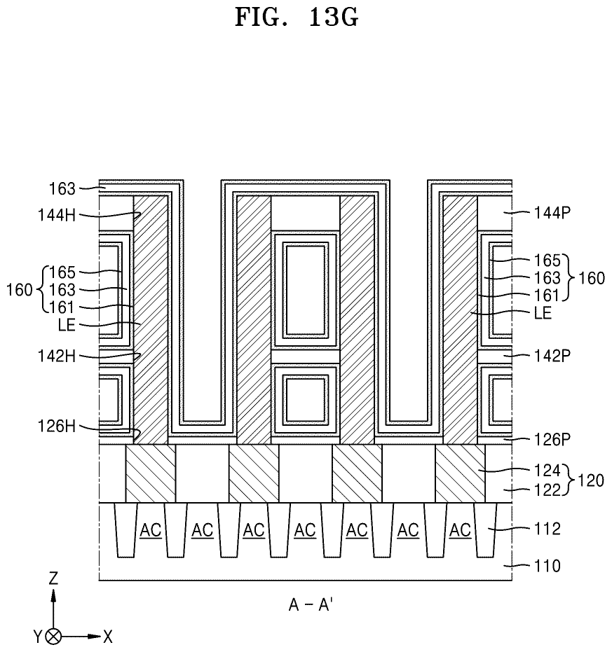

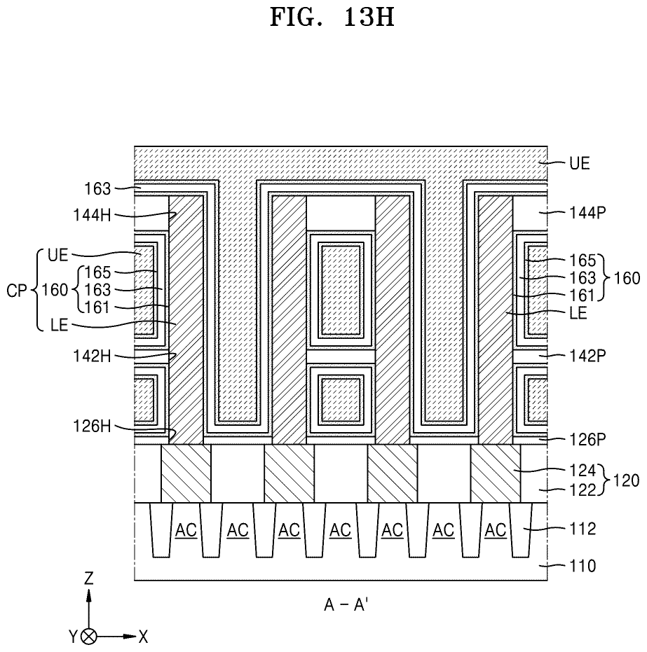

A lower supporter 142P may extend in parallel with the substrate 110 between the substrate 110 and the upper supporter 144P. A plurality of holes 142H penetrated by the plurality of lower electrodes LE and a plurality of lower holes LH (see FIG. 13E) may be formed in the lower supporter 142P. An inner sidewall of each of the plurality of holes 142H formed in the lower supporter 142P may be in contact with a sidewall of each of the lower electrodes LE.

The lower supporter 142P and the upper supporter 144P may include a silicon nitride (SiN) layer, a silicon carbon nitride (SiCN) layer, a silicon boron nitride (SiBN) layer, or a combination thereof, but example embodiments are not limited thereto. In various example embodiments, the lower supporter 142P and the upper supporter 144P may include the same material. For example, each of the lower supporter 142P and the upper supporter 144P may include SiCN. In some other example embodiments, the lower supporter 142P and the upper supporter 144P may include different materials from each other. For example, the lower supporter 142P may include SiCN, and the upper supporter 144P may include SiBN.

The dielectric layer structure 160 may be arranged between the lower electrode LE and the upper electrode UE. The dielectric layer structure 160 may include a first dielectric layer 161, a second dielectric layer 163, and a third dielectric layer 165. The first dielectric layer 161 may be in contact with the lower electrode LE, the second dielectric layer 163 may be arranged between the first dielectric layer 161 and the third dielectric layer 165, and the third dielectric layer 165 may be in contact with the upper electrode UE.

Each of the first dielectric layer 161, the second dielectric layer 163, and the third dielectric layer 165 may include a ferroelectric material and an anti-ferroelectric material. For example, the ferroelectric material may be HfO₂, and the anti-ferroelectric material may be ZrO₂. In this case, the ratio of the ferroelectric material and the anti-ferroelectric material included in each of the first dielectric layer 161, the second dielectric layer 163, and the third dielectric layer 165 may vary according to the characteristics required by the semiconductor device 100.

In various example embodiments, each of the first dielectric layer 161, the second dielectric layer 163, and the third dielectric layer 165 may include a same ferroelectric material and a same anti-ferroelectric material. For example, the first dielectric layer 161, the second dielectric layer 163, and the third dielectric layer 165 may include HfO₂ as a ferroelectric material and ZrO₂ as an anti-ferroelectric material.

In various example embodiments, the first dielectric layer 161 and the third dielectric layer 165 may each include a silicon dopant DP1. In various example embodiments, the silicon dopant DP1 may be present inside each of the first and third dielectric layers 161 and 165. In other example embodiments, the silicon dopant DP1 may exist at an interface where the first dielectric layer 161 and the lower electrode LE are in contact with each other and at an interface where the third dielectric layer 165 and the upper electrode UE are in contact with each other.

In various example embodiments, an atomic concentration of the silicon dopant DP1 included in the first dielectric layer 161 and an atomic concentration of the silicon dopant DP1 included in the third dielectric layer 165 may be in a range of about 1 atomic concentration % to about 10 atomic concentration %. For example, each of the first dielectric layer 161 and the third dielectric layer 165 may include a silicon dopant DP1 having about 5 atomic concentration %. When the atomic concentration of the silicon dopant DP1 included in the first dielectric layer 161 and the atomic concentration of the silicon dopant DP1 included in the third dielectric layer 165 exceed about 10 atomic concentration %, the crystallinity of the anti-ferroelectric material included in the first dielectric layer 161 and the anti-ferroelectric material included in the third dielectric layer 165 may be lowered, thereby deteriorating the properties of the anti-ferroelectric material and lowering the operational reliability of the semiconductor device 100.

In various example embodiments, a thickness 160t of the dielectric layer structure 160 may be in a range of about 10 Å to about 100 Å. In various example embodiments, a thickness 161t of the first dielectric layer 161 and a thickness 165t of the third dielectric layer 165 may be in a range of about 1 Å to about 10 Å. In various example embodiments, the thickness 161t of the first dielectric layer 161 may be the same as the thickness 165t of the third dielectric layer 165. For example, each of the thickness 161t of the first dielectric layer 161 and the thickness 165t of the third dielectric layer 165 may be about 3 Å. In various example embodiments, each of the thickness 161t of the first dielectric layer 161 and the thickness 165t of the third dielectric layer 165 may be different from each other. For example, the thickness 161t of the first dielectric layer 161 may be about 3 Å, and the thickness 165t of the third dielectric layer 165 may be about 5 Å. When the thickness 161t of the first dielectric layer 161 and the thickness 165t of the third dielectric layer 165 exceed about 10 Å, the second dielectric layer 163 and the lower electrode LE may be excessively spaced apart from each other, or the second dielectric layer 163 and the upper electrode UE may be excessively spaced apart from each other, thereby deteriorating electrical characteristics of the semiconductor device 100.

The upper electrode UE covers the dielectric layer structure 160 and may be spaced apart from the plurality of lower electrodes LE with the dielectric layer structure 160 therebetween.

Each of the plurality of lower electrodes LE and the upper electrodes UE may include a metal, a conductive metal oxide, a conductive metal nitride, a conductive metal oxynitride, or a combination thereof. In exemplary example embodiments, each of the plurality of lower and upper electrodes LE and UE may include Ti, Ti oxide, Ti nitride, Ti oxynitride, Co, Co oxide, Co nitride, Co oxynitride, Nb, Nb oxide, Nb nitride, Nb oxynitride, Sn, Sn oxide, Sn nitride, Sn oxynitride, or a combination thereof. For example, the plurality of lower and upper electrodes LE and UE may include TiN, CON, NbN, SnO₂, or a combination thereof, but materials constituting each of the plurality of lower and upper electrodes LE and UE are not limited thereto.

The semiconductor device 100 according to various example embodiments of the inventive concepts include a capacitor structure CP including a lower electrode LE, a dielectric layer structure 160, and an upper electrode UE. The dielectric layer structure 160 may include a first dielectric layer 161 including a ferroelectric material, an anti-ferroelectric material, and a silicon dopant DP1, a third dielectric layer 165 including a ferroelectric material, an anti-ferroelectric material, and a silicon dopant DP1, and a second dielectric layer 163 arranged between the first dielectric layer 161 and the second dielectric layer and including a ferroelectric material and an anti-ferroelectric material. In this case, the second dielectric layer 163 not including the silicon dopant DP1 may be spaced apart from the lower electrode LE by the first dielectric layer 161 including the silicon dopant DP1, and may be spaced apart from the upper electrode UE by the third dielectric layer 165 including the silicon dopant DP1. Therefore, when a dielectric layer including an anti-ferroelectric material such as ZrO₂ but not including a silicon dopant DP1 contacts the lower electrode LE and/or the upper electrode UE, a secondary phase material such as zirconium silicide or zirconium silicate may be reduced or prevented from being formed at an interface where the dielectric layer including the anti-ferroelectric material and the lower electrode LE and/or the upper electrode UE are in contact with each other during performing an annealing process for manufacturing the semiconductor device 100. Since the formation of the secondary phase material at the interface is reduced or prevented, the over-crystallization of the anti-ferroelectric material may be reduced or prevented, thereby improving the operation reliability of the semiconductor device 100.

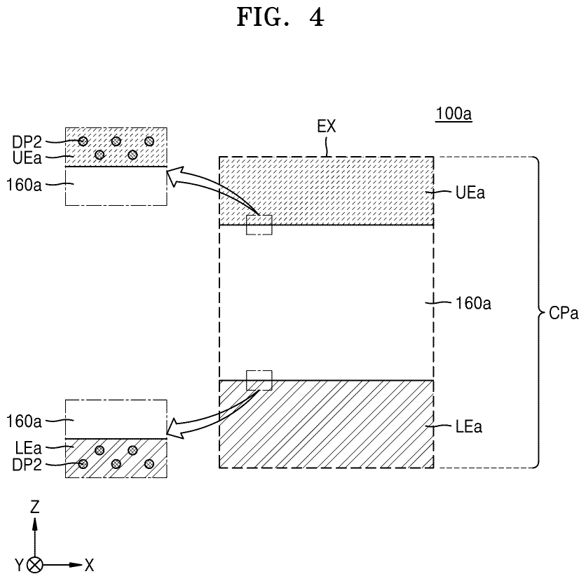

FIGS. 4, 5, 6, 7, and 8 are enlarged cross-sectional views illustrating a region corresponding to the region EX illustrated in FIG. 2, and are views for describing semiconductor devices 100a, 100b, 100c, 100d, and 100e according to various example embodiments. Since the components of the semiconductor devices 100a, 100b, 100c, 100d, and 100e illustrated in FIGS. 4, 5, 6, 7, and 8 are substantially the same as or similar to those of the semiconductor device 100 illustrated in FIGS. 1 to 3, only differences will be mainly described below.

Referring to FIG. 4, a semiconductor device 100a may have a configuration substantially the same as or similar to that of the semiconductor device 100 illustrated in FIGS. 1, 2, and 3, except that a dielectric layer structure 160a of a capacitor structure CPa includes a ferroelectric material and an anti-ferroelectric material, and does not include a silicon dopant DP2, and a silicon dopant DP2 is included at a portion adjacent to an interface where each of an upper electrode UEa and a lower electrode LEa is in contact with the dielectric layer structure 160a. That is, the silicon dopant DP2 may exist inside a portion of the lower electrode LEa, which is adjacent to the interface where the dielectric layer structure 160a and the lower electrode LEa are in contact with each other, and inside a portion of the upper electrode UEa, which is adjacent to the interface where the dielectric layer structure 160a and the upper electrode UEa are in contact with each other.

In various example embodiments, a thickness of the dielectric layer structure 160a may be in a range of about 10 Å to about 100 Å.

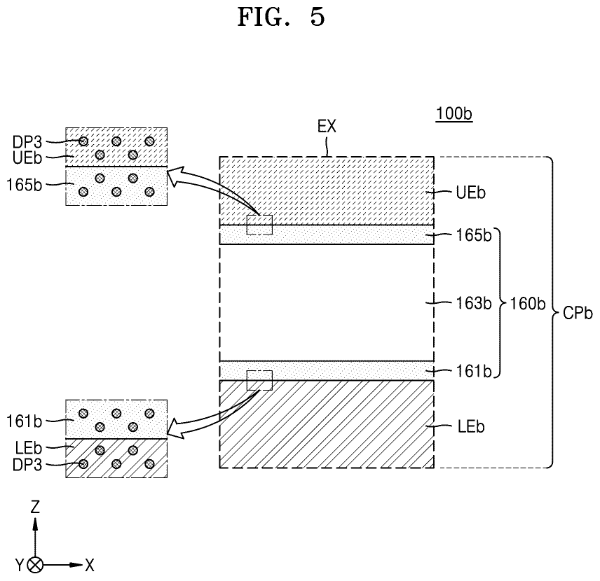

Referring to FIG. 5, a semiconductor device 100b may have a configuration substantially the same as or similar to that of the semiconductor device 100 illustrated in FIGS. 1, 2, and 3, except that a silicon dopant DP3 is included at a portion adjacent to an interface where each of an upper electrode UEb and a lower electrode LEb is in contact with a dielectric layer structure 160b.

In this case, the dielectric layer structure 160b of a capacitor structure CPb of the semiconductor device 100b may include a first dielectric layer 161b and a third dielectric layer 165b, which include a ferroelectric material, an anti-ferroelectric material, and a silicon dopant DP3, and a second dielectric layer 163b including a ferroelectric material and an anti-ferroelectric material but not including a silicon dopant DP3. That is, the silicon dopant DP3 may exist inside the first dielectric layer 161b, inside the third dielectric layer 165b, inside a portion of the upper electrode UEb, which is adjacent to the interface where the third dielectric layer 165b and the upper electrode UEb are in contact with each other, and inside a portion of the lower electrode LEb, which is adjacent to the interface wherein the first dielectric layer 161b and the lower electrode LEb are in contact with each other.

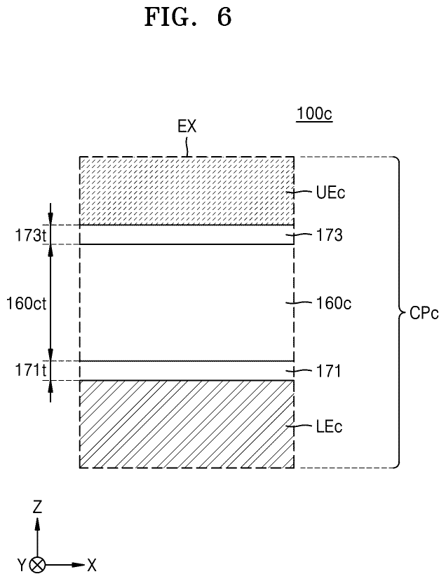

Referring to FIG. 6, a semiconductor device 100c may include a configuration substantially the same as or similar to that of the semiconductor device 100 illustrated in FIGS. 1, 2, and 3, except that a dielectric layer structure 160c of a capacitor structure CPc includes a ferroelectric material and an anti-ferroelectric material, and does not include a silicon dopant, and a first silicon layer 171 is included between the dielectric layer structure 160c and a lower electrode LEc, and a second silicon layer 173 is included between the dielectric layer structure 160c and an upper electrode UEc.

The first silicon layer 171 may separate the dielectric layer structure 160c and the lower electrode LEc from each other, and the second silicon layer 173 may separate the dielectric layer structure 160c and the upper electrode UEc from each other. Since the dielectric layer structure 160c is spaced apart from the lower electrode LEc and the upper electrode UEc by the first silicon layer 171 and the second silicon layer 173, when the dielectric layer structure 160c is in contact with the lower electrode LEc and the upper electrode UEc, a secondary phase material such as zirconium-silicide may be reduced or prevented from being formed at an interface where the dielectric layer structure 160c and the lower electrode LEc are in contact with each other and at an interface where the dielectric layer structure 160c and the upper electrode UEc are in contact with each other, during an annealing process.

In various example embodiments, a thickness 160ct of the dielectric layer structure 160c may be in a range of about 10 Å to about 100 Å. In various example embodiments, a thickness 171t of the first silicon layer 171 and a thickness 173t of the second silicon layer 173 may be in a range of about 1 Å to about 10 Å. In various example embodiments, the thickness 171t of the first silicon layer 171 may be the same as the thickness 173t of the second silicon layer 173. For example, each of the thickness 171t of the first silicon layer 171 and the thickness 173t of the second silicon layer 173 may be about 3 Å. In various example embodiments, the thickness 171t of the first silicon layer 171 may differ from the thickness 173t of the second silicon layer 173. For example, the thickness 171t of the first silicon layer 171 may be about 3 Å, and the thickness 173t of the second silicon layer 173 may be about 5 Å. When the thickness 171t of the first silicon layer 171 and the thickness 173t of the second silicon layer 173 exceed about 10 Å, the dielectric layer structure 160c and the lower electrode LE or the dielectric layer structure 160c and the upper electrode UE are excessively spaced apart from each other, and thus electrical characteristics of the semiconductor device 100c may be deteriorated.

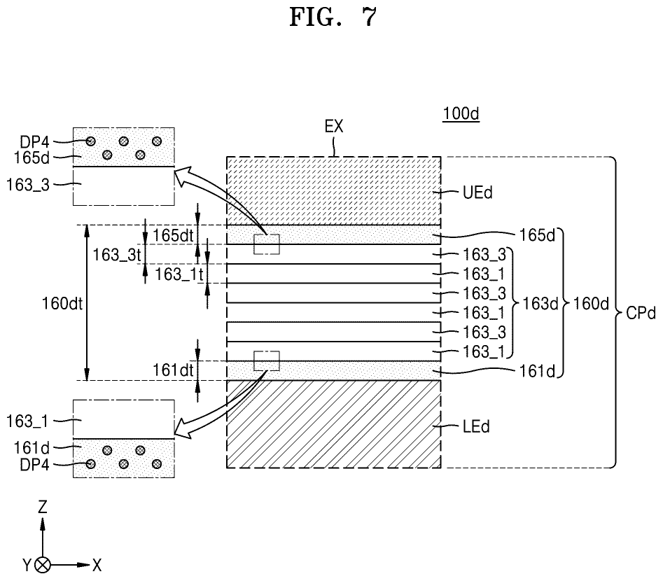

Referring to FIG. 7, a semiconductor device 100d may have a configuration substantially the same as or similar to that of the semiconductor device 100 illustrated in FIGS. 1, 2, and 3, except that a dielectric layer structure 160d of a capacitor structure CPd includes any one of a ferroelectric material and an anti-ferroelectric material, a first dielectric layer 161d and a third dielectric layer 165d including a silicon dopant DP4, and a second dielectric layer 163d including a plurality of ferroelectric material layers 163_1 and a plurality of anti-ferroelectric material layers 163_3.

In various example embodiments, the first dielectric layer 161d and the third dielectric layer 165d may include materials different from each other. For example, the first dielectric layer 161d may include an anti-ferroelectric material, but may not include a ferroelectric material, and the third dielectric layer 165d may include a ferroelectric material but may not include an anti-ferroelectric material. In various example embodiments, the first dielectric layer 161d and the third dielectric layer 165d may include an identical material. For example, the first dielectric layer 161d and the third dielectric layer 165d may include an anti-ferroelectric material.

The plurality of ferroelectric material layers 163_1 may include, for example, HfO₂, and the plurality of anti-ferroelectric material layers 163_3 may include, for example, ZrO₂.

In various example embodiments, the second dielectric layer 163d may have a structure in which the plurality of ferroelectric material layers 163_1 and the plurality of anti-ferroelectric material layers 163_3 are alternately stacked. For example, the first dielectric layer 161d may include a single layer including ZrO₂ and a silicon dopant DP4, the third dielectric layer 165d may include a single layer including HfO₂ and the silicon dopant DP4, and the second dielectric layer 163d may include a plurality of layers in which the plurality of ferroelectric material layers 163_1 including HfO₂ and the plurality of anti-ferroelectric material layers 163_3 including ZrO₂ are alternately stacked.

In various example embodiments, a thickness of a dielectric layer structure 160dt may be in a range of about 10 Å to about 100 Å. In various example embodiments, a thickness of a first dielectric layer 161dt and a thickness of a third dielectric layer 165dt may be in a range of about 1 Å to about 10 Å.

In various example embodiments, a thickness 163_1t of a plurality of ferroelectric material layers 163_1 and a thickness 163_3t of a plurality of anti-ferroelectric material layers 163_3 may be in a range of about 1 Å to about 10 Å. In various example embodiments, the thickness 163_1t of the plurality of ferroelectric material layers 163_1 may be the same as the thickness 163_3t of the plurality of anti-ferroelectric material layers 163_3. For example, each of the thicknesses 163_1t of the plurality of ferroelectric material layers 163_1 and the thicknesses 163_3t of the plurality of anti-ferroelectric material layers 163_3 may be about 1 Å. In various example embodiments, the thickness 163_1t of the plurality of ferroelectric material layers 163_1 may differ from the thickness 163_3t of the plurality of anti-ferroelectric material layers 163_3. For example, the thicknesses 163_1t of the plurality of ferroelectric material layers 163_1 may be about 1 Å, and the thicknesses 163_3t of the plurality of anti-ferroelectric material layers 163_3 may be about 2 Å.

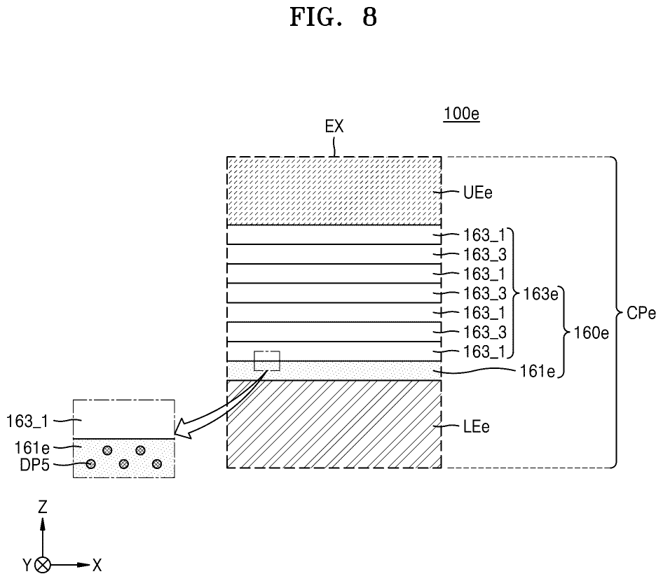

Referring to FIG. 8, a semiconductor device 100e may have a configuration substantially the same as or similar to that of the semiconductor device 100 illustrated in FIGS. 1, 2, and 3, except that a dielectric layer structure 160e of a capacitor structure CPe includes any one of a ferroelectric material and an anti-ferroelectric material, a first dielectric layer 161e including a silicon dopant DP5, and a second dielectric layer 163e including a ferroelectric material and an anti-ferroelectric material, wherein the second dielectric layer 163e includes a plurality of ferroelectric material layers 163_1 and a plurality of anti-ferroelectric material layers 163_3.

In various example embodiments, the first dielectric layer 161e may include an anti-ferroelectric material. For example, the anti-ferroelectric material may include ZrO₂.

The plurality of ferroelectric material layers 163_1 may include, for example, HfO₂, and the plurality of anti-ferroelectric material layers 163_3 may include, for example, ZrO₂.

In various example embodiments, the second dielectric layer 163e may have a structure in which the plurality of ferroelectric material layers 163_1 and the plurality of anti-ferroelectric material layers 163_3 are alternately stacked. For example, the first dielectric layer 161e may include a single layer including ZrO₂ and the silicon dopant DP5, and the second dielectric layer 163e may include a plurality of layers in which a plurality of ferroelectric material layers 163_1 including HfO₂ and a plurality of anti-ferroelectric material layers 163_3 including ZrO₂ are alternately stacked.

Although FIG. 8 illustrates that the first dielectric layer 161e including the silicon dopant is formed only between the second dielectric layer 163e and the lower electrode LEe, the various example embodiments of the inventive concepts are not limited thereto. For example, a dielectric layer including a silicon dopant may be formed only between the second dielectric layer 163e and the upper electrode UEe, and may not be formed between the second dielectric layer 163e and the lower electrode LEe.

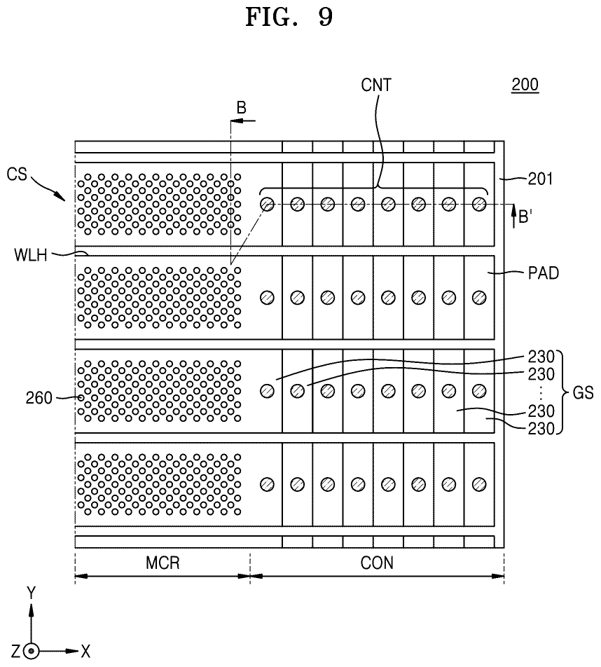

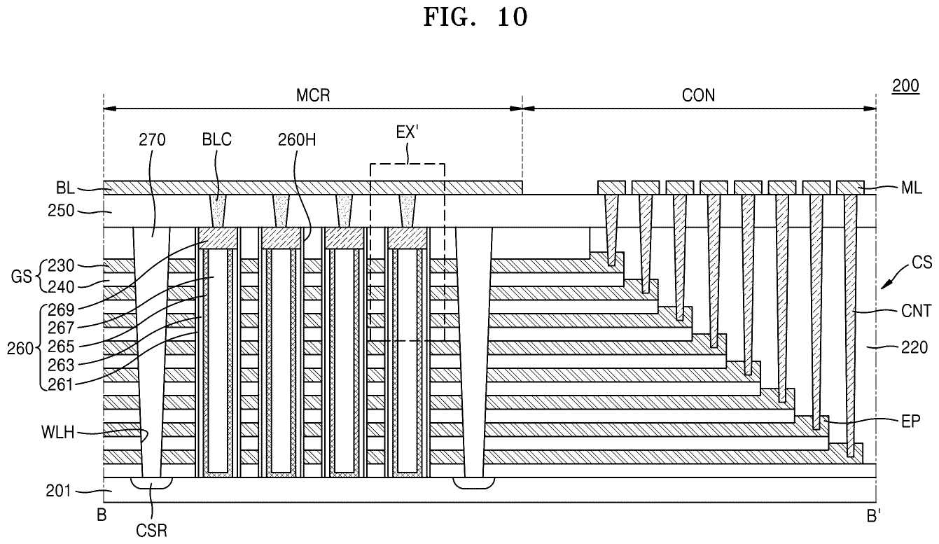

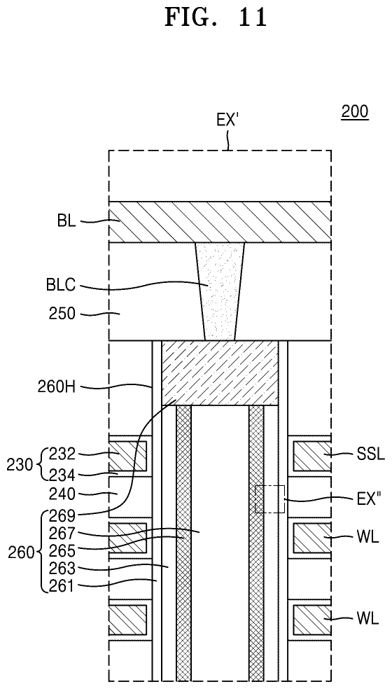

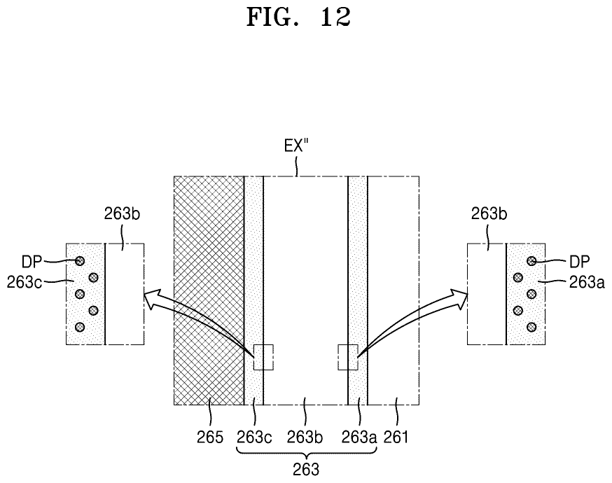

FIG. 9 is a layout diagram schematically illustrating components of a semiconductor device 200 according to various example embodiments. FIG. 10 is a cross-sectional view taken along line B-B′ of FIG. 9. FIG. 11 is an enlarged cross-sectional view of a region EX′ of FIG. 10. FIG. 12 is an enlarged cross-sectional view of a region EX″ of FIG. 11.

Referring to FIGS. 9, 10, 11, and 12, a semiconductor device 200 may include a cell array structure CS including a memory cell region MCR and a connection region CON. The memory cell region MCR may be a region in which a vertical channel structure NAND type memory cell array is formed. The connection region CON may be a region in which a rising end portion EP for electrical connection between the memory cell array and the peripheral circuit region (not shown) formed in the memory cell region MCR is arranged.

A substrate 201 may include a semiconductor element such as Si and Ge, or a compound semiconductor such as SiC, GaAs, InAs, and InP. However, example embodiments are not limited thereto. The substrate 201 may be provided as a bulk wafer or a wafer on which an epitaxial layer is formed. In other example embodiments, the substrate 201 may include a silicon on insulator (SOI) substrate or a germanium on insulator (GeOI) substrate.

A gate stack GS may extend on the substrate 201 in a first horizontal direction (X direction) and a second horizontal direction (Y direction) parallel to a top surface of the substrate 201. The gate stack GS may include a plurality of conductive lines 230 and a plurality of insulating layers 240. The plurality of conductive lines 230 and the plurality of insulating layers 240 may be alternately stacked in a vertical direction (Z direction) perpendicular to the top surface of the substrate 201. An upper insulating layer 250 may be arranged on the uppermost end of the gate stack GS.

Each of the plurality of conductive lines 230 may include a buried conductive layer 232 and an insulating liner 234 surrounding a top surface, a bottom surface, and a side surface of the buried conductive layer 232. The buried conductive layer 232 may include, for example, a metal such as tungsten, a metal silicide such as tungsten silicide, doped polysilicon, or a combination thereof. However, example embodiments are not limited thereto. In various example embodiments, the insulating liner 234 may include a high-k dielectric material such as aluminum oxide.

The plurality of conductive lines 230 may correspond to a ground selection line, a word line WL, and at least one string selection line SSL constituting a memory cell string. For example, the lowermost conductive line 230 may function as the ground selection line, the uppermost conductive line 230 may function as the string selection line SSL, and the rest of the conductive lines 230 except the uppermost and lowermost conductive lines 230 may function as the word lines WL.

Each of a plurality of word line cuts 270 may extend in the first horizontal direction (X direction) within a word line cut opening WLH. The word line cut 270 may include an insulating material. A gate stack GS arranged between the adjacent word line cuts 270 may constitute one block, and the adjacent word line cuts 170 may limit the width of the gate stack GS in the second horizontal direction (Y direction). A plurality of common source regions CSR may be formed in the substrate 201. The plurality of common source regions CSR may include impurity regions doped with impurities at a high concentration. The word line cut 270 may have a tapered shape in which a width in a horizontal direction is narrowed in a vertical direction (Z direction) from a top surface of the substrate 201 to a bottom surface of the upper insulating layer 250.

A plurality of channel structures 260 may extend in a vertical direction (Z direction) through the conductive line 230 from the top surface of the substrate 201 in the memory cell region MCR. The plurality of channel structures 260 may be arranged to be spaced apart from each other at predetermined intervals in the first horizontal direction (X direction) and the second horizontal direction (Y direction). The plurality of channel structures 260 may be arranged in a zigzag shape or a staggered shape.

The plurality of channel structures 260 may extend in the vertical direction (Z direction) inside a channel hole 260H penetrating the gate stack GS. Each of the plurality of channel structures 260 may include a blocking insulating layer 261 arranged along an inner sidewall of the channel hole 260H, a charge storage layer 263 arranged along an inner sidewall of the blocking insulating layer 261, a channel layer 265 arranged along an inner sidewall of the charge storage layer 263, a buried insulating layer 267 filling a center portion of the channel hole 260H, and a pad pattern 269 arranged to cover a top surface of the buried insulating layer 267.

Each of the plurality of channel structures 260 may be in contact with the substrate 201. In various example embodiments, the channel layer 265 may be arranged to be in contact with the top surface of the substrate 201 at the bottom portion of the channel hole 260H.

The blocking insulating layer 261 may cover all inner sidewalls of the channel hole 260H. In various example embodiments, the uppermost surface of the blocking insulating layer 261 may have a vertical level in the vertical direction (Z direction) higher than the uppermost surface of the charge storage layer 263 and the uppermost surface of the channel layer 265. That is, an outer sidewall of the blocking insulating layer 261 may be arranged in contact with the plurality of conductive lines 230, and an inner sidewall of the blocking insulating layer 261 may be arranged in contact with the charge storage layer 263 and the pad pattern 269. The blocking insulating layer 261 may include at least one of, for example, silicon oxide, silicon nitride, and silicon oxynitride. In various example embodiments, the blocking insulating layer 261 may include a high-k dielectric material.

The charge storage layer 263 may cover most of an inner sidewall of the blocking insulating layer 261. For example, the charge storage layer (263) may cover the rest of the inner sidewall of the blocking insulating layer 261, except for the upper end portion of the inner sidewall of the blocking insulating layer 261.

The charge storage layer 263 may include a first dielectric layer 263a, a second dielectric layer 263b, and a third dielectric layer 263c. The first dielectric layer 263a may be in contact with the inner sidewall of the blocking insulating layer 261, the third dielectric layer 263c may be in contact with the sidewall of the buried insulating layer 267, and the second dielectric layer 263b may be arranged between the first dielectric layer 263a and the third dielectric layer 263c.

The charge storage layer 263 may be substantially the same as or similar to the dielectric layer structure 160 illustrated in FIGS. 1 to 3. That is, the first dielectric layer 263a, the second dielectric layer 263b, and the third dielectric layer 263c have a structure substantially the same as or similar to the first dielectric layer 161, the second dielectric layer 163, and the third dielectric layer 165 illustrated in FIGS. 1 to 3, respectively, and may include substantially the same or similar material. For example, the first dielectric layer 263a, the second dielectric layer 263b, and the third dielectric layer 263c may include the same ferroelectric material and the same anti-ferroelectric material, but the first dielectric layer 263a and the third dielectric layer 263c may further include a silicon dopant.

However, the various example embodiments according to the inventive concepts are not limited thereto, and the charge storage layer 263 may have a structure substantially the same as or similar to the dielectric layer structures 160a, 160b, 160c, 160d, 160e, and 160f illustrated in FIGS. 4 to 8.

The channel layer 265 may cover all of the inner sidewall of the charge storage layer 263. In various example embodiments, the channel layer 265 may be formed in an annular shape surrounding the buried insulating layer 267 in the channel hole 260H, but example embodiments are not limited thereto. The channel layer 265 may include a semiconductor material layer. For example, the channel layer 265 may include an undoped polysilicon (Si) layer or a polysilicon (Si) layer including p-type or n-type impurities.

The buried insulating layer 267 may fill the channel hole 260H and may be arranged in the central portion of the channel hole 260H. The buried insulating layer 267 may extend in the vertical direction (Z direction). The buried insulating layer 267 may include a silicon oxide or a low-k dielectric material. However, example embodiments are not limited thereto.

The pad pattern 269 fills an upper portion of the channel hole 260H and may be arranged on the buried insulating layer 267. The pad pattern 269 may include, for example, polysilicon including p-type or n-type impurities.

The outer sidewall of the pad pattern 269 and the outer sidewall of the charge storage layer 263 may be coplanar and may be in contact with the inner sidewall of the blocking insulating layer 261.

In the connection region CON, a rising end portion EP and a cover insulating layer 220 covering the rising end portion EP may be arranged at an end portion of the conductive line 230. The rising end portion EP of the conductive line 230 may have an increased thickness compared to other portions of the conductive line 230. That is, the rising end portion EP may have a top surface positioned at a higher vertical level than other portions of the conductive line 230, but example embodiments are not limited thereto.

In the connection region CON, the plurality of conductive lines 230 may extend to have a shorter length in the first horizontal direction (X direction) as they move away from the top surface of the substrate 201 in the vertical direction (Z direction). That is, the plurality of conductive lines 230 may have a stepped structure in the connection region CON.

In the connection region CON, a contact plug CNT may penetrate the cover insulating layer 220 and may be connected to the rising end portion EP of the conductive line 230. The contact plug CNT may have a tapered pillar shape having a width which is narrowed in a vertical direction (Z direction) from an upper region to a lower region.

Although not illustrated in FIGS. 9 to 12, a plurality of dummy channel structures extending in a vertical direction (Z direction) through the gate stack GS may be arranged in the connection region CON. The dummy channel structure may reduce or prevent bending or warping of the gate stack GS in the manufacturing process of the semiconductor device 200 and may provide improved structural stability.

A bit line contact BLC may penetrate the upper insulating layer 250 to be in contact with the pad pattern 269 of the channel structure 260, and a bit line BL in contact with the bit line contact BLC may extend in the second horizontal direction (Y direction) on the upper insulating layer 250.

In the connection region CON, a conductive line ML may be formed on the upper insulation layer 250. Although not shown in FIGS. 9 to 12, an upper support layer may be further formed between the upper insulating layer 250 and the bit line BL and between the upper insulating layer 250 and the conductive line ML.

FIGS. 13A, 13B, 13C, 13D, 13E, 13F, 13G, and 13H are cross-sectional views illustrating a method of manufacturing a semiconductor device 100 according to various example embodiments.

Referring to FIG. 13A, a substrate 110 in which a plurality of active regions AC are defined by device isolation layers 112, is provided and a lower structure 120 including a plurality of insulating structures 122 and a plurality of conductive regions 124 penetrating the plurality of insulating structures 122 and connected to each of the active regions AC may be formed on the provided substrate 110. Next, an insulating layer 126 covering the lower structure 120 may be formed.

The insulating layer 126 may be used as an etching stop layer in a manufacturing process of the semiconductor device 100. The insulating layer 126 may include an insulating material having etch selectivity with respect to the plurality of insulating structures 122. In various example embodiments, the insulating layer 126 may include a silicon nitride (SiN) layer, a silicon carbon nitride (SiCN) layer, a silicon boron nitride (SiBN) layer, or a combination thereof. However, example embodiments are not limited thereto.

Referring to FIG. 13B, a mold structure MST may be formed on the insulating layer 126. The mold structure MST may include a first mold layer 132, a lower support layer 142, a second mold layer 134, and an upper support layer 144 sequentially stacked on the insulating layer 126. Each of the first mold layer 132 and the second mold layer 134 may include a material having a relatively high etch rate with respect to an etchant including ammonium fluoride (NH₄F), hydrofluoric acid (HF), and water. In various example embodiments, each of the first mold layer 132 and the second mold layer 134 may include an oxide layer, a nitride layer, or a combination thereof. For example, the first mold layer 132 may be made of a borophosphosilicate glass (BPSG) layer, and the second mold layer 134 may include a multi-insulating layer in which a relatively thin silicon oxide layer and a silicon nitride layer are alternately stacked multiple times, or a silicon nitride layer. However, constituent materials of each of the first mold layer 132 and the second mold layer 134 are not limited thereto.

The lower supporter 142 and the upper supporter 144 may include a silicon nitride (SiN) layer, a silicon carbon nitride (SiCN) layer, a silicon boron nitride (SiBN) layer, or a combination thereof. However, example embodiments are not limited thereto. In various example embodiments, the lower supporter 142 and the upper supporter 144 may include the same material. In some other example embodiments, the lower supporter 142 and the upper supporter 144 may include different materials from each other.

Referring to FIG. 13C, after forming a mask pattern MP on the mold structure MST in the result of FIG. 13B, a mold structure pattern MSP having a plurality of holes BH may be formed by etching the mold structure MST by using the mask pattern MP as an etching mask and the insulating layer 126 as an etching stop layer. The mold structure pattern MSP may include a first mold pattern 132P, a lower supporter 142P, a second mold pattern 134P, and an upper supporter 244P.

The mask pattern MP may include a nitride layer, an oxide layer, a polysilicon layer, a photoresist layer, or a combination thereof. However, example embodiments are not limited thereto.

A process of forming the plurality of holes BH may further include etching the mold structure MST and wet-treating the etched mold structure MST. During the wet treatment process, a portion of the insulating layer 126 may be etched to obtain the insulating pattern 126P having the plurality of openings 126H exposing the plurality of conductive regions 124. The wet treatment process may use, for example, an etchant including a diluted sulfuric acid peroxide (DSP) solution, but example embodiments are not limited thereto.

In the mold structure pattern MSP, the plurality of holes 142H constituting a portion of the plurality of holes BH may be formed in the lower supporter 142P, and the plurality of holes 144H constituting a portion of the plurality of holes BH may be formed in the upper supporter 144P.

Referring to FIG. 13D, after the mask pattern MP is removed from the result of FIG. 13C, the lower electrode LE filling the plurality of holes BH may be formed.

In order to form the lower electrode LE, a conductive layer covering a top surface of the upper supporter 144P while filling the plurality of holes BH may be formed. A process of forming the conductive layer may include, for example, a CVD, PECVD, metal organic CVD (MOCVD), or atomic layer deposition (ALD) process. However, example embodiments are not limited thereto. After the conductive layer is formed, a portion of the conductive layer may be removed using an etch-back process or a chemical mechanical polishing (CMP) process to expose the top surface of the upper supporter 144P.

Referring to FIG. 13E, after a portion of the upper supporter 144P is removed from the result of FIG. 13D to form a plurality of upper holes UH, the second mold pattern 134P may be removed through the plurality of upper holes UH. Next, after a portion of the lower supporter 142P exposed through the plurality of upper holes UH is removed to form a plurality of lower holes LH, the first mold pattern 132P may be removed through the plurality of lower holes LH. Each of the plurality of upper holes UH and each of the plurality of lower holes LH may communicate with each other, and the top surface of the insulating pattern 126P may be exposed through the plurality of upper holes UH and the plurality of lower holes LH. In addition, the first mold pattern 132P and the second mold pattern 134P may be removed, so that the sidewalls of the plurality of lower electrodes LE may be exposed.

In various example embodiments, the second mold pattern 134P and the first mold pattern 132P may be removed in a wet manner. The wet removal process may use, for example, an etchant including ammonium fluoride (NH₄F), hydrofluoric acid (HF), and water, but example embodiments are not limited thereto.

Referring to FIG. 13F, a dielectric material layer 160S may be formed to cover sidewalls of the plurality of exposed lower electrodes LE, some surfaces of the lower supporter 142P and the upper supporter 144P, and some surfaces of the insulating pattern 126P. The dielectric material layer 160S may be formed by using a CVD, MOCVD, PVD, or ALD process. However, example embodiments are not limited thereto. In various example embodiments, the dielectric material layer 160S may include a single layer including a ferroelectric material such as HfO₂ and an anti-ferroelectric material such as ZrO₂. In various example embodiments, the dielectric material layer 160S may be formed by alternately stacking ferroelectric material layers and anti-ferroelectric material layers. In this case, when a process to be described later with reference to FIGS. 13E to 13G is performed, the semiconductor device 100d illustrated in FIG. 7 or the semiconductor device 100e illustrated in FIG. 8 may be manufactured.

In various example embodiments, after the process described with reference to FIG. 13E is performed, the first silicon layer 171 (see FIG. 6) covering the sidewalls of the plurality of exposed lower electrodes LE, some surfaces of the lower supporter 142P and the upper supporter 144P, and some surfaces of the insulating pattern 126P may be formed, and the dielectric material layer 160S may be formed and the second silicon layer 173 (see FIG. 6) covering the dielectric material layer 160S may be formed as described with reference to FIG. 13F. In this case, the injection process of the silicon dopant to be described later with reference to FIG. 13G may be omitted, and after the second silicon layer 173 is formed, an annealing process and a process of forming an upper electrode UE to be described later with reference to FIG. 13H may be performed to manufacture the semiconductor device 100c illustrated in FIG. 6.

Referring to FIG. 13G, a silicon dopant may be injected into a region of the dielectric material layer 160S (see FIG. 13F) adjacent to the lower electrode LE and a region of the dielectric material layer 160S (see FIG. 13F) adjacent to the exposed surface of the dielectric material layer 160S. The silicon dopant may be, for example, Si. After the injection process is performed, a region of the dielectric material layer 160S (see FIG. 13F) including the silicon dopant adjacent to the lower electrode LE may be defined as the first dielectric layer 161, a region of the dielectric material layer 160S (see FIG. 13F) including the silicon dopant adjacent to the exposed surface of the dielectric material layer 160S (see FIG. 13F) may be defined as the third dielectric layer 165, and the remaining region of the dielectric material layer 160S (see FIG. 13F) into which the silicon dopant is not injected may be defined as the second dielectric layer 163.

In various example embodiments, after the process described with reference to FIG. 13E is performed, a silicon dopant is injected on the exposed surface of the lower electrode LE, the dielectric material layer 160S is formed as described with reference to FIG. 13G, and an injection process of the silicon dopant described with reference to FIG. 13G may be omitted. In this case, a process to be described later with reference to FIG. 13H may be performed to manufacture the semiconductor device 100a illustrated in FIG. 3.

In various example embodiments, after the process described with reference to FIG. 13E is performed, a silicon dopant is injected on the exposed surface of the lower electrode LE, the dielectric material layer 160S is formed as described with reference to FIG. 13G, and an injection process of the silicon dopant described with reference to FIG. 13G may be performed. In this case, a process to be described later with reference to FIG. 13H may be performed to manufacture the semiconductor device 100b illustrated in FIG. 4.

Referring to FIG. 13H, the upper electrode UE covering the dielectric layer structure 160 may be formed. In various example embodiments, the upper electrode UE may be formed using a CVD, MOCVD, PVD, or ALD process. However, example embodiments are not limited thereto.

Next, an annealing process of the first dielectric layer 161, the second dielectric layer 163, and the third dielectric layer 165 may be performed. In various example embodiments, the annealing process may be performed at a temperature of about 200° C. to about 700° C. Crystallinity of each of the first dielectric layer 161, the second dielectric layer 163, and the third dielectric layer 165 may be improved by the annealing process. In addition, since the second dielectric layer 163, which includes ferroelectric and anti-ferroelectric materials but does not include silicon dopants, is separated from the lower and upper electrodes LE and UE between the first and third dielectric layers 161 and 165, secondary phase materials such as zirconium-silicide may be reduced or prevented from being formed at the interfaces where the dielectric layer, which does not include silicon dopants, and the lower and upper electrodes LE and UE contact each other during the annealing process.

The annealing process may be performed to manufacture the semiconductor device 100 illustrated in FIGS. 1, 2, and 3.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the inventive concepts has been particularly shown and described with reference to various example embodiments thereof, it will be understood that various changes in form and details may be made therein without departing from the spirit and scope of the following claims.

What is claimed is:

1. A semiconductor device comprising:
a lower electrode;
an upper electrode on the lower electrode; and
a dielectric layer structure between the lower electrode and the upper electrode; and
wherein the dielectric layer structure includes
a first dielectric layer in contact with the lower electrode,
a second dielectric layer in contact with the first dielectric layer, and
a third dielectric layer in contact with the upper electrode,
wherein the first dielectric layer, the second dielectric layer, and the third dielectric layer include an anti-ferroelectric material, and
wherein the anti-ferroelectric material of the first, second, and third dielectric layers are of the same material type, and
a silicon dopant is included in a region adjacent to an interface between the first dielectric layer and the lower electrode, and a region adjacent to an interface between the third dielectric layer and the upper electrode.

2. The semiconductor device of claim 1, wherein each of an atomic concentration of a silicon dopant of the first dielectric layer and an atomic concentration of a silicon dopant of the third dielectric layer is in a range from 1 atomic % to 10 atomic %.

3. The semiconductor device of claim 1, wherein a thickness of the dielectric layer structure is in a range from 10 Å to 100 Å, and each of a thickness of the first dielectric layer and a thickness of the third dielectric layer is in a range from 1 Å to 10 Å.

4. The semiconductor device of claim 3, wherein the thickness of the first dielectric layer is the same as the thickness of the third dielectric layer.

5. The semiconductor device of claim 3, wherein the thickness of the first dielectric layer differs from the thickness of the third dielectric layer.

6. The semiconductor device of claim 1, wherein the silicon dopant is present inside the first dielectric layer and inside the third dielectric layer.

7. The semiconductor device of claim 1, wherein the silicon dopant is present inside at least a portion of the lower electrode adjacent to an interface between the first dielectric layer and the lower electrode, and
the silicon dopant is present inside at least a portion of the upper electrode adjacent to an interface between the third dielectric layer and the upper electrode.

8. The semiconductor device of claim 1, wherein the silicon dopant is present inside
the first dielectric layer,
the third dielectric layer,
at least a portion of the lower electrode adjacent to an interface between the first dielectric layer and the lower electrode, and
at least a portion of the upper electrode adjacent to an interface between the third dielectric layer and the upper electrode.

9. The semiconductor device of claim 1, wherein the silicon dopant is present at an interface between the first dielectric layer and the lower electrode, and
the silicon dopant is present at an interface between the third dielectric layer and the upper electrode.

10. A semiconductor device comprising:
a lower electrode;
an upper electrode on the lower electrode; and
a dielectric layer structure between the lower electrode and the upper electrode, and
wherein the dielectric layer structure includes
a first dielectric layer in contact with the lower electrode,
a second dielectric layer in contact with the first dielectric layer, and
a third dielectric layer in contact with the upper electrode,
wherein the second dielectric layer includes
a plurality of ferroelectric material layers and a plurality of anti-ferroelectric material layers alternately stacked, and
a silicon dopant is included in at least one of a region adjacent to an interface between the first dielectric layer and the lower electrode, and
a region adjacent to an interface between the third dielectric layer and the upper electrode.

11. The semiconductor device of claim 10, wherein one of the first dielectric layer and the third dielectric layer includes an anti-ferroelectric material, and the other of the first dielectric layer and the third dielectric layer includes a ferroelectric material.

12. The semiconductor device of claim 11, wherein the silicon dopant is present inside at least one of the first dielectric layer and the third dielectric layer including an anti-ferroelectric material.

13. The semiconductor device of claim 11, wherein the silicon dopant is present in at least one of the interface between the first dielectric layer and the lower electrode, or the interface between the third dielectric layer and the upper electrode.

14. The semiconductor device of claim 10, wherein each of the first dielectric layer and the third dielectric layer includes an anti-ferroelectric material.

15. The semiconductor device of claim 14, wherein the silicon dopant is present inside each of the first dielectric layer and the third dielectric layer.

16. The semiconductor device of claim 14, wherein the silicon dopant is present at an interface between the first dielectric layer and the lower electrode and at an interface between the third dielectric layer and the upper electrode.

17. The semiconductor device of claim 10, wherein a thickness of the dielectric layer structure is in a range from 10 Å to 100 Å, and
a thickness of each of the plurality of ferroelectric material layers and a thickness of each of the plurality of anti-ferroelectric material layers are in a range from 1 Å to 10 Å.

18. The semiconductor device of claim 10, wherein each of the first dielectric layer and the second dielectric layer has a thickness in a range from 1 Å to 10 Å.

19. A semiconductor device comprising:
a substrate having a plurality of active regions defined by device isolation layers;
a lower structure on the substrate and connected to the plurality of active regions; and
a capacitor structure on the lower structure and connected to the lower structure,
wherein the capacitor structure includes
a lower electrode,
an upper electrode on the lower electrode, and
a dielectric layer structure between the lower electrode and the upper electrode,
wherein the dielectric layer structure includes
a first dielectric layer in contact with the lower electrode,
a second dielectric layer in contact with the first dielectric layer, and
a third dielectric layer in contact with the upper electrode,
wherein each of the first dielectric layer, the second dielectric layer, and the third dielectric layer includes at least one of HfO₂ and ZrO₂, and
a silicon dopant is included inside of the first dielectric layer and inside of the third dielectric layer.

20. The semiconductor device of claim 19, wherein each of an atomic concentration of the silicon dopant of the first dielectric layer and an atomic concentration of the silicon dopant of the third dielectric layer is in a range from 1 atomic % to 10 atomic %.
